(19) United States
(12) Patent Application Publication
(10) Pub. No.: US 2026/0331184 A1
(43) Pub. Date: Oct. 22, 2026

(54) MULTI-LEVEL SENSING IN A MEMORY DEVICE WITH IN-PILLAR AMPLIFICATION

(71) Applicant: Micron Technology, Inc., Boise, ID (US)

(72) Inventors: Yoshihiko Kamata, Yokohama (JP); Gianfranco Valeri, Pescina (IT); Ottavio Nuccilli, Aielli (IT); Koichi Kawai, Yokohama (JP); Shigekazu Yamada, Tokyo (JP)

(21) Appl. No.: 19/468,662

(22) Filed: Feb. 3, 2026

Related U.S. Application Data
(60) Provisional application No. 63/753,830, filed on Feb. 4, 2025.

(51) Int. Cl. G11C 16/26; G11C 16/04; G11C 16/08; G11C 16/24

(52) U.S. Cl. CPC G11C 16/26; G11C 16/0483; G11C 16/08; G11C 16/24

(57) ABSTRACT

A memory device includes a memory array comprising a plurality of blocks of memory cells, wherein a plurality of respective bitlines is coupled to the plurality of blocks, and wherein each block includes a plurality of strings of memory cells coupled between a common source and an in-block sense node and a sense transistor having a gate terminal coupled to the in-block sense node. The memory device further includes a page buffer circuit coupled to the plurality of respective bitlines, and control logic, operatively coupled with the memory array and the page buffer circuit, to perform certain operations. The operations include initiating a sense operation on a first block of the plurality of blocks of memory cells, the sense operation to generate a cell voltage on a first bitline of the plurality of respective bitlines, the cell voltage representing a voltage at the in-block sense node, and causing the common source of the first block to be biased to a supply voltage during the sense operation.

### RELATED APPLICATIONS

This application claims the benefit of priority from U.S. Provisional Patent Application No. 63/753,830, filed Feb. 4, 2025, the entire contents of which are hereby incorporated by reference herein.

### TECHNICAL FIELD

Embodiments of the disclosure relate generally to memory sub-systems, and more specifically, relate to multi-level sensing in a memory device with in-pillar amplification in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic of portions of an array of memory cells as could be used in a memory of the type described with reference to FIG. 1B in accordance with some embodiments of the present disclosure.

FIG. 3 is a block diagram illustrating a memory device architecture with in-pillar amplification for multi-level source-follower sensing in accordance with some embodiments of the present disclosure.

FIG. 4 is a block diagram illustrating a switched capacitance pull-down network for a memory device in accordance with some embodiments of the present disclosure.

FIG. 5 is a flow diagram of an example method of performing a multi-level sensing operation in a memory device with in-pillar amplification in accordance with some embodiments of the present disclosure.

FIG. 6 is a block diagram of an example computer system in which embodiments of the present disclosure can operate.

### DETAILED DESCRIPTION

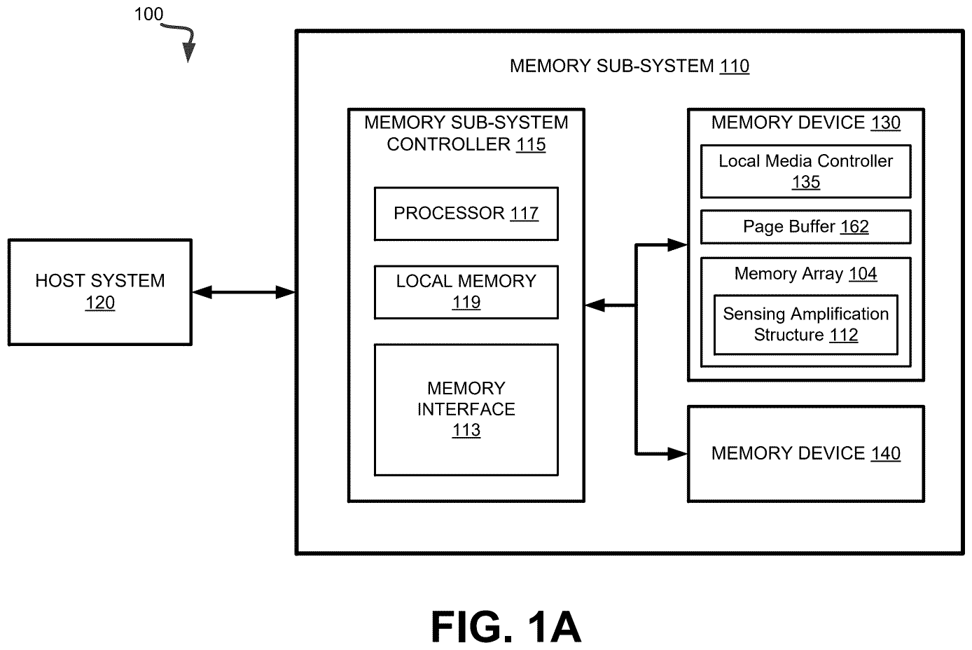

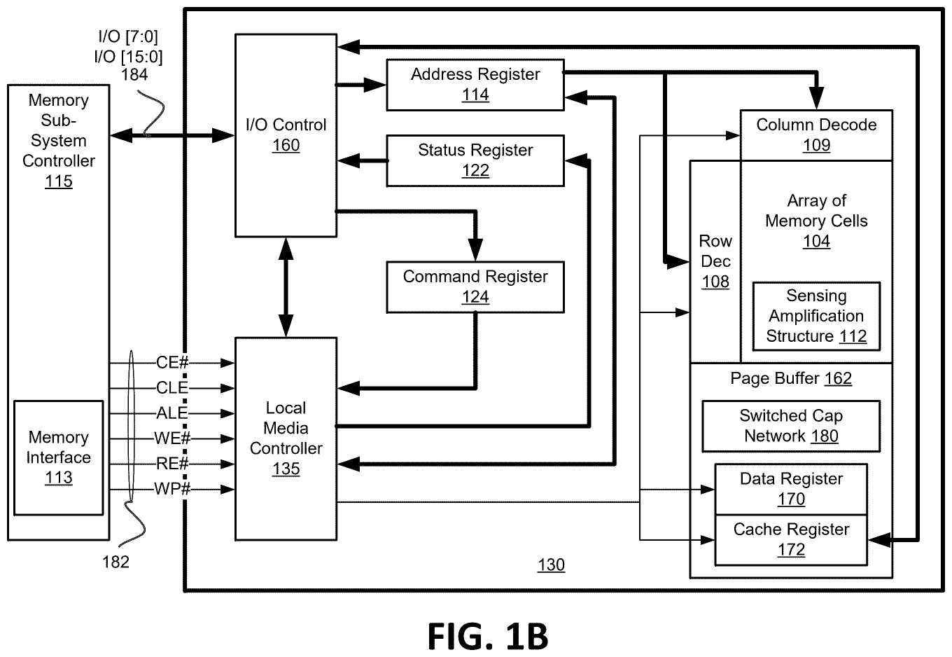

Aspects of the present disclosure are directed to multi-level sensing in a memory device with in-pillar amplification in a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high-density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

Each data block can include a number of sub-blocks, where each sub-block is defined by an associated pillar (e.g., a vertical conductive trace) extending from a shared bitline. Since the sub-blocks can be accessed separately (e.g., to perform program or read operations), the data block can include a structure to selectively enable the pillar associated with a certain sub-block, while disabling the pillars associated with other sub-blocks. In one embodiment, this structure includes one or more select gate devices positioned at either or both ends of each pillar. Depending on a control signal applied, these select gate devices can either enable or disable the conduction of signals through the pillars. For example, when a read operation is being performed on memory cells in a selected block or sub-block, one or more selected memory cells can be read by the application of a read voltage to a selected wordline associated with those memory cells. If the respective threshold voltages (Vts) of the target memory cells are identified as being below the applied read voltage, then the data stored at the target cell can be read as a particular value (e.g., a logical ‘1’) or determined to be in a particular state (e.g., a “set” state). If the threshold voltage of the specified memory cell is identified as being above the read voltage, then the data stored at the specified memory cell can be read as another value (e.g., a logical ‘0’) or determined to be in another state (e.g., a “reset” state). A given level for a set of cells may have a range of threshold voltages (e.g., such as a normal distribution of threshold voltages). An electric current corresponding to the voltage of the memory cells being read is transmitted through the pillar and along the bitline associated with the selected block or sub-block to sensing circuitry in the memory device, such as a page buffer circuit.

To perform a sensing operation on the memory cells in a block, a read voltage can be applied on one or more associated wordlines of the block to determine whether a given threshold voltage stored in the memory cells has been reached. Depending on the cell type, a cell can store one or more bits of binary information, and has various logic states that correlate to the number of bits being stored, where each logic state has a corresponding threshold voltage level. The logic states can be represented by binary values, such as “0” and “1”, or combinations of such values. For example, a single level cell (SLC) can store one bit of information and has two logic states. Similarly, a multi-level cell (MLC) can store two bits per cell, a triple level cell (TLC) can store three bits per cell, a quad level cell (QLC) can store four bits per cell, and a penta level cell (PLC) can store five bits per cell. Some memory device can implement multi-level sensing operations, where the read voltage is adjusted through multiple different levels in order to detect cells in different logic states during the same operation. Such a multi-level sensing operation requires high precision, however, in order to allow the page buffer sensing circuitry to accurately differentiate between the threshold voltages corresponding to the different logic states.

Given that there are multiple blocks and multiple sub-blocks in a memory device, each with a corresponding bitline, when concurrent sense operations (e.g., read or program verify operations) are being performed, the possibility exists that different currents, and thus different voltages, are present on the different bitlines. Similarly, when one bitline associated with a selected block or sub-block is at a given voltage level representing the threshold voltage of the memory cell being read from the selected block or sub-block, an adjacent bitline associated with an unselected block or sub-block may be at a different voltage (e.g., a ground or floating voltage). Given the physical proximity of the different bitlines, some amount of capacitive coupling (i.e., interference) between the different bitlines may occur. As a result, the current on the selected bitline may be decreased, for example, resulting in an inaccurate threshold voltage being sensed at the page buffer circuit and a corresponding read or program verify error, such as a sensed memory cell threshold voltage error.

Aspects of the present disclosure address the above and other deficiencies by implementing in-pillar amplification and using source-follower sensing in order to improve the accuracy of multi-level sensing in the memory device. In one embodiment, the memory device includes a number of blocks of memory cells, coupled to a page buffer circuit by a corresponding number of bitlines. In one embodiment, each block includes a number of strings of memory cells coupled between a common source and an in-block sense node, as well as a sense transistor having a gate terminal coupled to the in-block sense node. Control logic in the memory device can initiate a sense operation using a source-follower sensing technique. For example, the control logic can cause a read voltage to be applied to one or more wordlines coupled to the memory cells for a first period of time, where the read voltage is adjusted through a plurality of different levels, while causing the common source of the block to be biased to a supply voltage during the sense operation. This permits the cell voltage read from the cells to be stored at the in-block sense node and passed along the wordlines to the page buffer circuit and the read voltage can be removed from the wordlines for the remainder of the sense operation.

Advantages of this approach include, but are not limited to, improved performance in the memory sub-system. The in-pillar amplification provided by the sense transistor located in each block of the memory device amplifies the cell voltage sent on the bitline to the page buffer circuit to reduce or eliminate capacitive coupling between adjacent bitlines, which reduces sense errors and improves sense accuracy. Furthermore, limiting the period of time for which the read voltage is applied to the memory cells reduces the wear placed on the memory cells, which increases endurance and reliability in the memory device.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the physical host interface (e.g., PCIe or CXL interface). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional

### NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some embodiments, one or more components of memory sub-system 110 can be omitted.

In one embodiment, the memory sub-system 110 includes a memory interface 113 that is responsible for handling interactions of memory sub-system controller 115 with the memory devices of memory sub-system 110, such as memory device 130. For example, the memory interface 113 can send memory access commands corresponding to requests received from host system 120 to memory device 130, such as program commands, read commands, or other commands. In addition, the memory interface 113 can receive data from memory device 130, such as data retrieved in response to a read command or a confirmation that a program command was successfully performed. In some embodiments, the memory sub-system controller 115 includes at least a portion of the memory interface 113. For example, the memory sub-system controller 115 can include a processor 117 (processing device) configured to execute instructions stored in local memory 119 for performing the operations described herein.

In one embodiment, memory device 130 includes a page buffer circuit 162 that is connected to memory array 104. The page buffer circuit 162 can include a number of registers and sensing devices that are used to perform memory access operations, including read, program, program verify, erase, and other operations, on the memory cells in memory array 104 (e.g., in response to control signals provided by local media controller 135). In one embodiment, the page buffer circuit 162 includes switched capacitance pull-down network, which can generate a pull-down tail current on different bitlines of the memory array 104 in order to reduce the capacitive coupling between the bitlines when concurrent sense operations are being performed, such as when a multi-level sensing operation is active.

In one embodiment, each block of the memory array 104 includes a dedicated sensing amplification structure 112 that amplifies the string current on the bitline in order to improve the signal-to-noise ratio between the block and the page buffer circuit 162 and increase sensing accuracy in the page buffer circuit 162. The sensing amplification structure 112 can include a sense transistor (TFT) having a gate terminal coupled to the bitline, among other transistors. In one embodiment, the gate terminal represents an in-block sense node, which reflects the threshold voltage present on a selected memory cell or cells in the memory array 104 on which the source-follower-sense operation is being performed. Further details with regards to the structure and operations of the sensing amplification structure 112 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In one embodiment, memory sub-system controller 115 includes memory interface 113.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states. In one embodiment, each block in the array of memory cells 104 includes a dedicated sensing amplification structure 112 that amplifies a string current on the bitline in order to improve the signal-to-noise ratio between the block and the page buffer circuit 162 during source-follower sensing operations.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer 162 of the memory device 130. The page buffer 162 may further include sensing devices (not shown in FIG. 1B) to sense a data state of a memory cell of the array of memory cells 104 (e.g., by sensing a state of a data line connected to that memory cell). In one embodiment, the page buffer 162 further includes switched capacitance pull-down network 180 to generate a pull-down tail current on different data lines (i.e., bitlines) of the memory array 104 in order to reduce the capacitive coupling between the bitlines when a multi-level sense operation is being performed. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 182. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 182 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 184 and outputs data to the memory sub-system controller 115 over I/O bus 184.

For example, the commands may be received over input/output (I/O) pins [7: 0] of I/O bus 184 at I/O control circuitry 160 and may then be written into command register 124. The addresses may be received over input/output (I/O) pins [7: 0] of I/O bus 184 at I/O control circuitry 160 and may then be written into address register 114. The data may be received over input/output (I/O) pins [7: 0] for an 8-bit device or input/output (I/O) pins [15: 0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7: 0] for an 8-bit device or input/output (I/O) pins [15: 0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

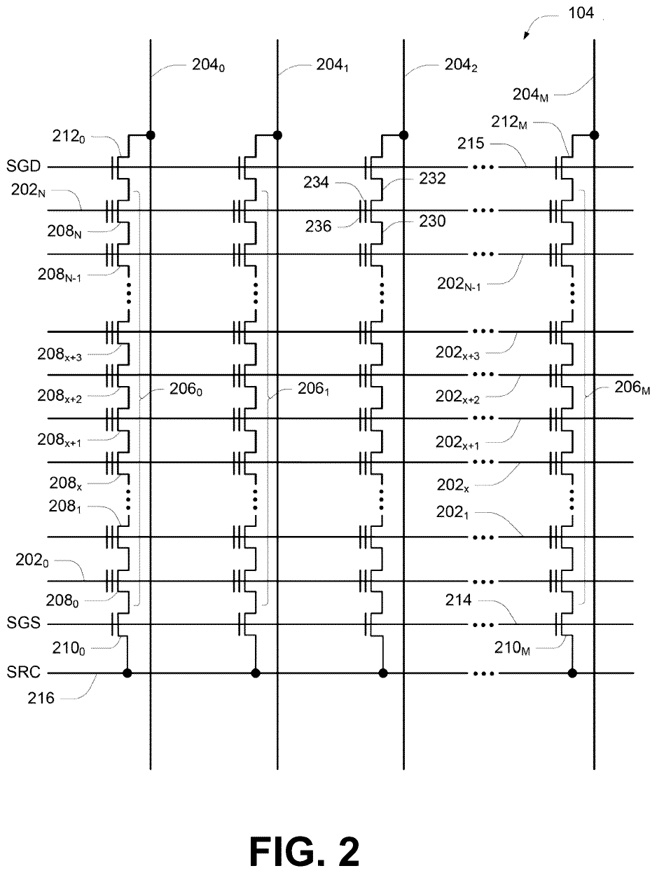

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N}, and data lines, such as bitlines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 104 in FIG. 2 can be a quasi-two-dimensional memory array and can have a generally planar structure, e.g., where the common source 216, NAND strings 206 and bitlines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bitlines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 104 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

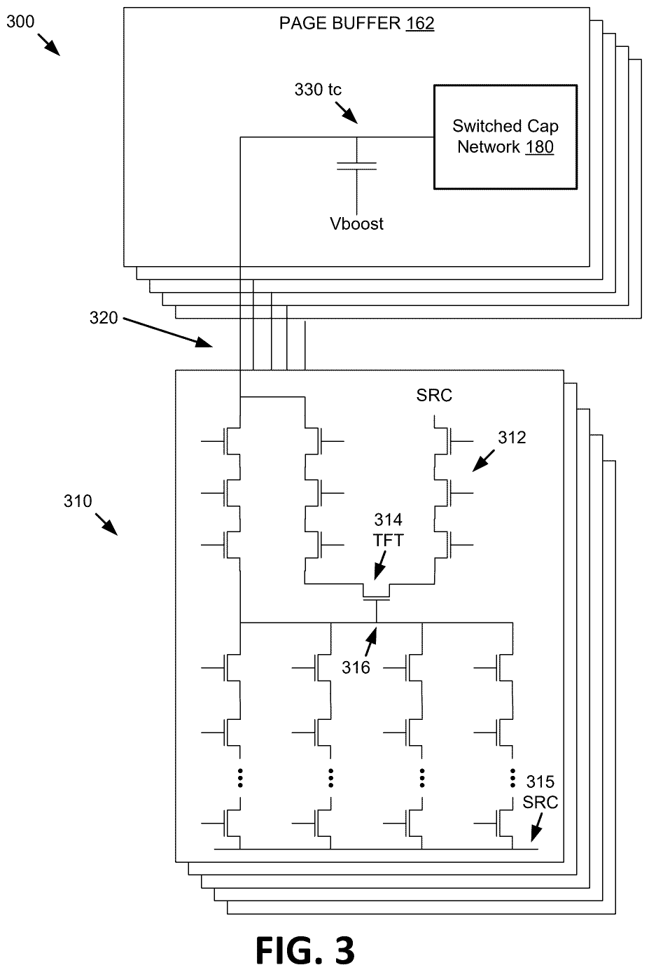

FIG. 3 is a block diagram illustrating a memory device architecture with in-pillar amplification for multi-level source-follower sensing in accordance with some embodiments of the present disclosure. In one embodiment, the architecture 300 represents at least a portion of memory device 130 and includes a number of blocks 310, each connected to a respective corresponding page buffer circuit, such as page buffer circuit 162, by respective data lines, such as bitlines 320. Each of blocks 310 includes a number of memory cells, which may be arranged into a number of sub-blocks, and form at least a portion of the memory array 104 described above. For example, the memory cells in each block 310 may be arranged in vertical strings of memory cells descending from one of the bitlines 320 and terminating at a common source node (SRC) 315. In one embodiment, each block 310 further includes a dedicated sensing amplification structure 312 that amplifies the string current on the bitline in order to improve the signal-to-noise ratio and increase sensing accuracy in the page buffer circuit 162. The sensing amplification structure 312 can include a sense transistor (TFT) 314 having a gate terminal 316 coupled to the bitline, among other transistors. In one embodiment, the gate terminal 316 represents an in-block sense node. Page buffer circuit 162 includes a sense node (tc) 330 coupled to the corresponding one of the bitlines 320, to a boost capacitor, and to switched capacitance pull-down network 180. It should be understood that page buffer circuit 162 includes numerous other components which are not illustrated in FIG. 3 in order to simplify the drawing.

During a multi-level sensing operation, multiple memory cells, such as those in strings of memory cells coupled to different bitlines and which may be programmed to different threshold voltage levels representing different bit values, may be read concurrently (i.e., at least partially overlapping in time. The voltage on the respective bitlines will be reflective of the corresponding threshold voltages of the different memory cells. For example, if a higher level cell is turned off, the corresponding bitline 320 will remain in a floating state (i.e., a high-impedance state). If the adjacent bitline is coupled to a lower level cell that is turned on, however, a current through the string of memory cells will raise the voltage on that adjacent bitline to a supply voltage (i.e., Vcc). Thus, the original bitline 320 in the floating state can become susceptible to capacitive coupling of voltage from the adjacent bitline. When the voltage on the original bitline is sampled at the sense node 330 in the page buffer circuit 162, the loss of voltage from the original bitline due to the capacitive coupling can lead to a sensed memory cell threshold voltage error and an incorrect reading of the state of the memory cells coupled to the original bitline.

During a multi-level sensing operation, multiple memory cells, such as those in strings of memory cells coupled to different bitlines and which may be programmed to different threshold voltage levels representing different bit values, may be read concurrently (i.e., at least partially overlapping in time). The voltage on the respective bitlines will be reflective of the corresponding threshold voltages of the different memory cells. For example, if a given memory cell is on, it will draw a string current through the string of memory cells and discharge the gate capacitance at the gate terminal 316 of the sense transistor 314 (i.e., at the in-block sense node), thereby turning the sense transistor 314 off. Conversely, if the memory cell is off, the string current will be close to zero and the gate capacitance remains at a high state, thereby turning the sense transistor 314 on. The state of the sense transistor 314 is transferred to the page buffer circuit 162 by amplifying the current on the corresponding bitline 320 and the analog voltage sampled at sense node 330 is based on the voltage at the gate terminal 316 of the sense transistor 314. For example, when the memory cell is on, the sense transistor 314 will be off, the current on the bitline 320 is close to zero, and the voltage at the sense node 330 will be high. When the memory cell is off, the sense transistor will be on, the current on the bitline 320 is stronger and will discharge the voltage at the sense node 330.

In another embodiment, the architecture 300 may be utilized with a source-follower sensing technique where the common source (SRC) 315 in each block 310 is biased to a supply voltage (e.g., Vcc). In this embodiment, if a given memory cell is fully on, the supply voltage will flow through the memory pillar to the gate terminal 316 and activate the sense transistor 314. When the sense transistor 314 is turned on, the current on the bitline 320 is amplified higher and will discharge the voltage at the sense node 330. If the memory cell being sensed is at some intermediate level (i.e., representing one of a number of different programming states L1, L2, L3, etc.), the analog voltage at the gate terminal 316 (i.e., the in-block sense node) will vary according to the state of the memory cell. This state is similarly transferred to the page buffer 162 via the current on the bitline 320. If the memory cell is off, the gate terminal 316 remains floating and the sense transistor 314 will be off. Accordingly, the current on the bitline 320 is close to zero, and the voltage at the sense node 330 will be high.

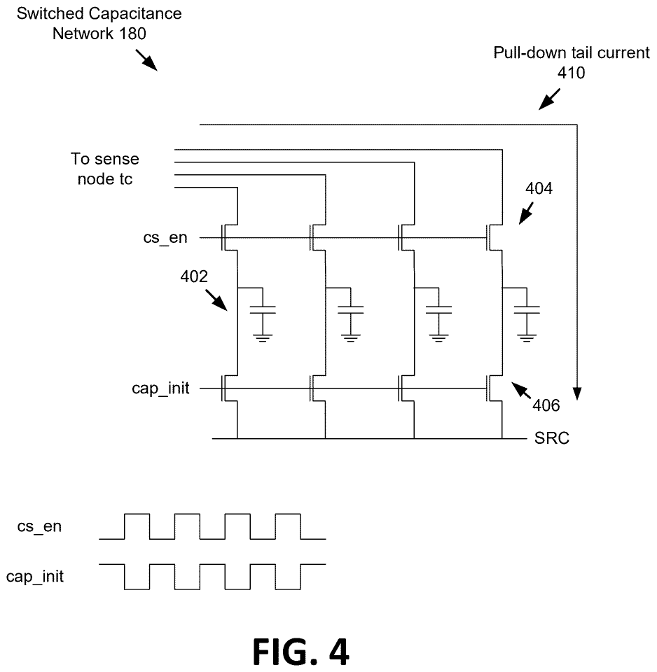

If the current on the bitline 320 is affected by capacitive coupling from an adjacent bitline, however, the voltage at the sense node 330 can change leading to a sensed memory cell threshold voltage error and an incorrect reading of the state of the memory cells coupled to the original bitline. In one embodiment, page buffer circuit 162 includes a switched capacitance pull-down network 180 which can be used to improve the multi-level sensing in the memory device 130. The switched capacitance pull-down network 180 can generate a pull-down tail current on the different bitlines 320 in order to reduce the capacitive coupling between the bitlines when concurrent sense operations are being performed. The pull-down tail current will decrease the voltage on the adjacent bitline 320, thereby suppressing the capacitive coupling to the original bitline 320 (i.e., the bitline coupled to the memory cell being read). Thus, the voltage sampled at the sense node 330 will be reflective of the actual state of the memory cell being read and any sensed memory cell threshold voltage error will be reduced. In another embodiment (not illustrated), the switched capacitance pull-down network 180 can be connected to the bitline 320 and positioned before the sense node 330 in page buffer 162. Additional details of the switched capacitance pull-down network 180 are described below with respect to FIG. 4.

FIG. 4 is a block diagram illustrating a switched capacitance pull-down network 180 for a memory device in accordance with some embodiments of the present disclosure. As described above, switched capacitance pull-down network 180 may be coupled to the sense node within a page buffer circuit 162 of a memory device 130 to generate a pull-down tail current on bitlines in the memory device in order to suppress capacitive coupling between the bitlines during multi-level sense operations. In one embodiment, the switched capacitance pull-down network 180 includes a series of capacitors 402 coupled between respective pairs of switching transistors 404 and 406. There can be one capacitor 402 and one pair of switching transistors 404 and 406 corresponding to each bitline in the memory device 130. The switching transistors 404 and 406 are controlled by respective control signals, which are received from a local memory controller 135 for example, and are alternately activated to continuously charge and discharge the capacitors 402. This operation generates the pull-down tail current 410 in the non-selected bitlines, which reduces the capacitive coupling between bitlines and suppresses the sensed memory cell threshold voltage error on the selected bitline.

In one embodiment, the transistors 404 are controlled by a first control signal, charge_share_enable (cs_en), and the transistors 406 are controlled by a second control signal, capacitance_initialize_enable (cap_init). The first and second control signals are alternately active so that only one of either transistors 404 or 406 are turned on at once. For example, the second control signal cap_init may be active during a first period, such that the source-side transistors 406 are turned on, allowing the capacitors 402 to be initialized to the source voltage (e.g., ground). Then, during a second period, the second control signal cap_init may be deactivated, such that the source-side transistors 406 are turned off, and the first control signal cs_en may be activated, such at the bitline-side transistors 404 are turned on to charge the capacitors 402 from the respective bitlines. In a third period, the first control signal cs_en may be deactivated, such at the bitline-side transistors 404 are turned off, and the second control signal cap_init may be activated, such that the source-side transistors 406 are turned on allowing the capacitors 402 to discharge to the common source. These periods are subsequently repeated and the continuous charging and discharging of the capacitors 402 generates the pull-down tail current 410 that flows from the bitlines through the switched capacitance pull-down network 180 to the common source. As noted above, the pull-down tail current 410 discharges the voltage from the non-selected bitlines to reduce capacitive coupling with the selected bitlines.

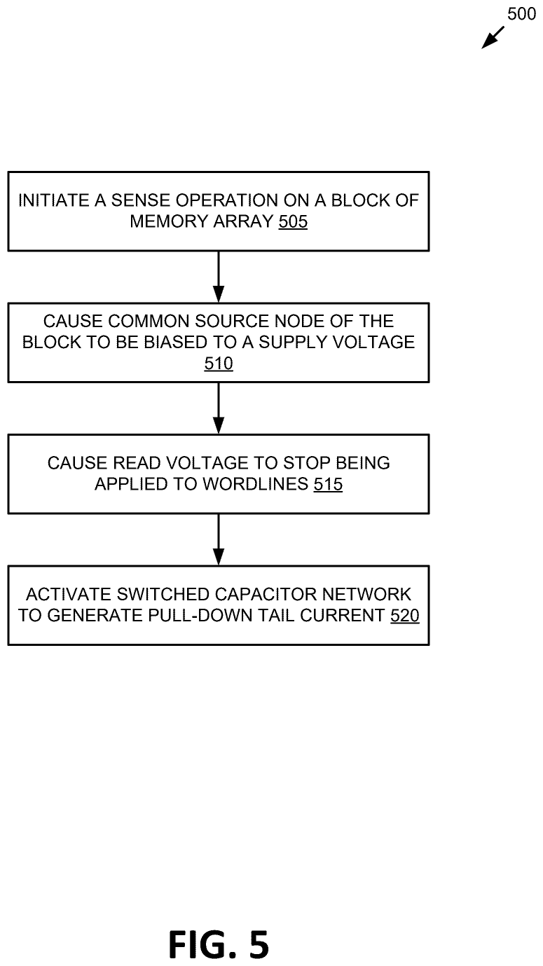

FIG. 5 is a flow diagram of an example method of performing a multi-level sensing operation in a memory device with in-pillar amplification in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by local media controller 135 using switched capacitance pull-down network 180 of FIG. 1A and FIG. 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, a sense operation is initiated. For example, the processing logic (e.g., local media controller 135) can initiate a sense operation on a first block of a plurality of blocks of memory cells, such as one of blocks 310. The sense operation can include a read operation or a program verify operation, for example, and may generate a cell voltage on a first bitline of a plurality of respective bitlines, such as bitlines 320 coupling the blocks 310 to a page buffer circuit 162. In one embodiment, the cell voltage can represent a voltage at an in-block sense node, such as gate terminal 316 of a sense transistor 314, if present in the first block. Depending on the implementation, the sense operation may include a multi-level sensing operation and/or may utilize a source-follower sensing technique to read data from memory cells in the first block. In one embodiment, as part of the sense operation, the processing logic causes a read voltage to be applied to one or more wordlines, such as wordlines 202, coupled to the memory cells for a first period of time. In multi-level sensing operations, the read voltage can be adjusted through multiple different levels in order to detect cells in different logic states during the same operation.

At operation 510, a source node is biased. For example, as part of the source-follower sensing technique, the processing logic can cause a common source (SRC) 315 of the first block to be biased to a supply voltage (e.g., Vcc) during the sense operation, such that the cell voltage can be stored at the gate terminal 426 of the in-block sense node during the first period of time Thus, if a given memory cell is fully on when a given read voltage is applied to the corresponding wordline, the supply voltage will flow through the memory pillar to the gate terminal 316 and activate the sense transistor 314. When the sense transistor 314 is turned on, the current on the bitline 320 is amplified higher and will discharge the voltage at the sense node 330 in the page buffer circuit 162. If the memory cell being sensed is at some intermediate level (i.e., representing one of a number of different programming states L1, L2, L3, etc.), the analog voltage at the gate terminal 316 (i.e., the in-block sense node) will vary according to the state of the memory cell. This state is similarly transferred to the page buffer 162 via the current on the bitline 320. If the memory cell is off, the gate terminal 316 remains floating and the sense transistor 314 will be off. Accordingly, the current on the bitline 320 is close to zero, and the voltage at the sense node 330 will be high.

At operation 515, the read voltage is no longer applied. For example, the processing logic can cause the read voltage to stop being applied to the one or more wordlines after the first period of time. Since the cell voltage (i.e., the threshold voltage read from the memory cell) has been transferred to the in-block sense node (i.e., the gate terminal 316 of the sense transistor 314), it is no longer necessary to continue applying the read voltage to the memory cell. Even though the read voltage is no longer applied, the sense operation can continue using the stored cell voltage, which can be interpreted by page buffer circuit 162. As such, the first period of time, may be less than the total time that the sense operation takes to complete. By limiting the period of time for which the read voltage is applied to the memory cell, less wear is placed on the memory cells, which increases endurance and reliability in the memory device.

At operation 520, a switched capacitor network is activated. For example, the processing logic can activate the switched capacitor network 180 to generate a pull-down tail current 410 on one or more of the plurality of respective bitlines adjacent to the first bitline during the sense operation. In one embodiment, the switched capacitor network comprises a plurality of respective capacitors 402 and a plurality of respective pairs of switching transistors 404 and 406, where the plurality of respective capacitors 402 are coupled between the plurality of respective pairs of switching transistors 404 and 406 and coupled to the plurality of respective bitlines 320. For example, each respective pair of switching transistors can include a bitline switching transistor 404 coupled to one of the plurality of bitlines 320 and to a first terminal of a respective switching capacitor 402. The pair of switching transistors can further include a source switching transistor 406 coupled to a common source line and to a second terminal of the respective switching capacitor 402.

In one embodiment, activating the switched capacitor network 180 to generate the pull-down tail current 410 comprises alternately applying a first control signal (e.g., cs_en) to activate the bitline switching transistor 404 and a second control signal (e.g., cap_init) to activate the source switching transistor 406. When the bitline switching transistor is activated, the respective capacitor 402 is charged by a voltage from a respective bitline, and when the source switching transistor 406 is activated, the respective capacitor 402 is discharged to the common source line. As these control signals continue to alternate during the sense operation, the continuous charging and discharging of the capacitor 402 generates the pull-down tail current 410 that flows from the bitline through the switched capacitance pull-down network 180 to the common source. As noted above, the pull-down tail current 410 discharges the voltage from the non-selected bitlines to reduce capacitive coupling with the selected bitlines and suppress the sensed memory cell threshold voltage error on the first (i.e., selected) bitline.

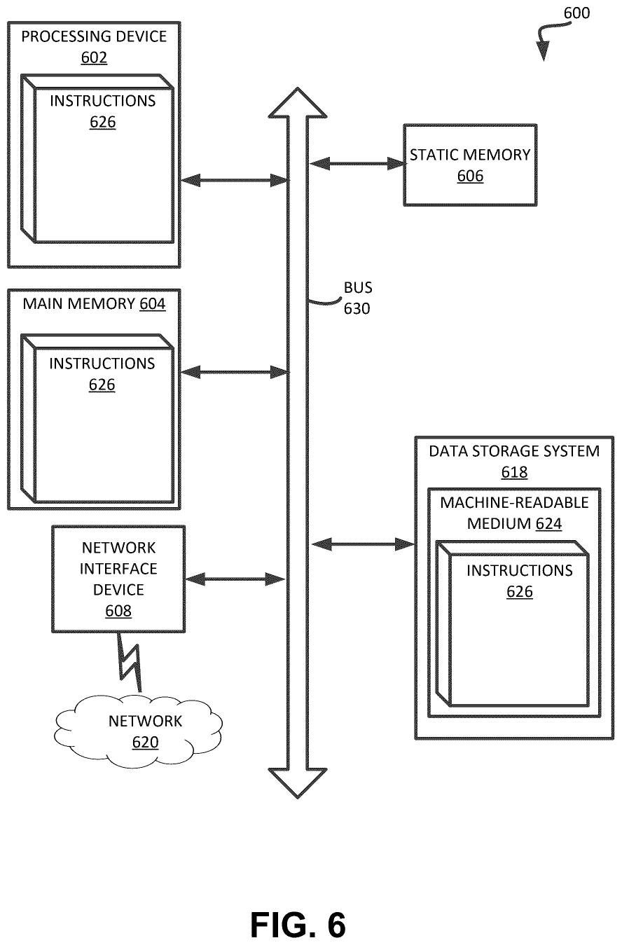

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to memory sub-system controller 115 or local media controller 135 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1A.

In one embodiment, the instructions 626 include instructions to implement functionality corresponding to the memory sub-system controller 115 or local media controller 135 of FIG. 1A. While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory device comprising:
a memory array comprising a plurality of blocks of memory cells, wherein a plurality of respective bitlines is coupled to the plurality of blocks, and wherein each block comprises:
a plurality of strings of memory cells coupled between a common source and an in-block sense node; and
a sense transistor having a gate terminal coupled to the in-block sense node; a page buffer circuit coupled to the plurality of respective bitlines; and
control logic, operatively coupled with the memory array and the page buffer circuit, to perform operations comprising:
initiating a sense operation on a first block of the plurality of blocks of memory cells, the sense operation to generate a cell voltage on a first bitline of the plurality of respective bitlines, the cell voltage representing a voltage at the in-block sense node; and
causing the common source of the first block to be biased to a supply voltage during the sense operation.

2. The memory device of claim 1, wherein initiating the sense operation comprises causing a read voltage to be applied to one or more wordlines coupled to the memory cells for a first period of time, wherein the read voltage is adjusted through a plurality of different levels.

3. The memory device of claim 2, wherein the causing the common source of the first block to be biased to the supply voltage causes the cell voltage to be stored at the gate terminal of the sense transistor during the first period of time.

4. The memory device of claim 3, wherein the control logic is to perform operations further comprising:
causing the read voltage to stop being applied to the one or more wordlines after the first period of time.

5. The memory device of claim 1, wherein the page buffer circuit comprises a switched capacitor network coupled to the plurality of respective bitlines, and wherein the control logic is to perform operations further comprising:
activating the switched capacitor network to generate a pull-down tail current on one or more of the plurality of respective bitlines adjacent to the first bitline during the sense operation.

6. The memory device of claim 5, wherein the switched capacitor network comprises:
a plurality of respective capacitors; and
a plurality of respective pairs of switching transistors,
wherein the plurality of respective capacitors are coupled between the plurality of respective pairs of switching transistors and coupled to the plurality of respective bitlines.

7. The memory device of claim 6, wherein each respective pair of switching transistors comprises:
a bitline switching transistor coupled to one of the plurality of bitlines and to a first terminal of a respective switching capacitor; and
a source switching transistor coupled to a common source line and to a second terminal of the respective switching capacitor.

8. The memory device of claim 7, wherein activating the switched capacitor network to generate the pull-down tail current comprises alternately applying a first control signal to activate the bitline switching transistor and a second control signal to activate the source switching transistor.

9. A method comprising:
initiating a sense operation on a first block of a plurality of blocks of memory cells in a memory array of a memory device, the sense operation to generate a cell voltage on a first bitline of a plurality of respective bitlines coupled to the plurality of blocks, wherein each block of the plurality of blocks comprises:
a plurality of strings of memory cells coupled between a common source and an in-block sense node; and
a sense transistor having a gate terminal coupled to the in-block sense node; and
causing the common source of the first block to be biased to a supply voltage during the sense operation.

10. The method of claim 9, wherein initiating the sense operation comprises causing a read voltage to be applied to one or more wordlines coupled to the memory cells for a first period of time, wherein the read voltage is adjusted through a plurality of different levels.

11. The method of claim 10, wherein the causing the common source of the first block to be biased to the supply voltage causes the cell voltage to be stored at the gate terminal of the sense transistor during the first period of time.

12. The method of claim 11, further comprising:
causing the read voltage to stop being applied to the one or more wordlines after the first period of time.

13. The method of claim 9, wherein the plurality of respective bitlines couple the plurality of blocks to a page buffer circuit, the page buffer circuit comprising a switched capacitor network coupled to the plurality of respective bitlines, and wherein the method further comprises:
activating the switched capacitor network to generate a pull-down tail current on one or more of the plurality of respective bitlines adjacent to the first bitline during the sense operation.

14. The method of claim 13, wherein the switched capacitor network comprises:
a plurality of respective capacitors; and
a plurality of respective pairs of switching transistors,
wherein the plurality of respective capacitors are coupled between the plurality of respective pairs of switching transistors and coupled to the plurality of respective bitlines.

15. The method of claim 14, wherein each respective pair of switching transistors comprises:
a bitline switching transistor coupled to one of the plurality of bitlines and to a first terminal of a respective switching capacitor; and
a source switching transistor coupled to a common source line and to a second terminal of the respective switching capacitor.

16. The method of claim 15, wherein activating the switched capacitor network to generate the pull-down tail current comprises alternately applying a first control signal to activate the bitline switching transistor and a second control signal to activate the source switching transistor.

17. A memory device comprising:
a page buffer circuit coupled to a plurality of respective bitlines; and
a memory array comprising a plurality of blocks of memory cells coupled to the plurality of respective bitlines, wherein each block comprises:
a plurality of strings of memory cells coupled between a common source and an in-block sense node; and
a sense transistor having a gate terminal coupled to the in-block sense node, wherein a cell voltage read from one of the memory cells is stored at the in-block sense node to activate the sense transistor during a sense operation, and wherein the common source is biased to a supply voltage during the sense operation.

18. The memory device of claim 17, wherein a read voltage is applied to one or more wordlines coupled to the memory cells during the sense operation for a first period of time, and wherein the read voltage is adjusted through a plurality of different levels.

19. The memory device of claim 18, wherein the read voltage is not applied to the one or more wordlines after the first period of time in the sense operation.

20. The memory device of claim 17, wherein the page buffer circuit comprises a switched capacitor network coupled to the plurality of respective bitlines, the switched capacitor network to generate a pull-down tail current on one or more of the plurality of respective bitlines during the sense operation.
